(19) United States
(12) Patent Application Publication
(10) Pub. No.: US 2005/0280069 A1
(43) Pub. Date: Dec. 22, 2005

(54) Semiconductor device and method of manufacturing the same

(76) Inventors: Ichiro Mizushima, Yokohama-shi (JP); Tetsuya Kai, Yokohama-shi (JP); Yoshio Ozawa, Yokohama-shi (JP); Kouichi Muraoka, Sagamihara-shi (JP); Shinichi Nakamura, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/923,831

(22) Filed: Aug. 24, 2004

(30) Foreign Application Priority Data
Jun. 21, 2004 (JP) 2004-182864

(51) Int. Cl. H01L 29/76

(52) U.S. Cl. 257/314

(57) ABSTRACT

A semiconductor device using a high dielectric constant insulator having reduced leak current as an interelectrode insulator is provided by comprising a first insulator formed on a semiconductor substrate, a first gate electrode formed on the first insulator, a second gate electrode formed above the first gate electrode, and a second crystallized insulator formed between the first gate electrode and the second gate electrode.

### CROSS-REFERENCE TO RELATED APPLICATIONS

This application is based upon and claims the benefit of priority from prior Japanese Patent Application No. 2004-182864, filed Jun. 21, 2004, the entire contents of which are incorporated herein by reference.

### BACKGROUND OF THE INVENTION

1. Field of the Invention

The present invention relates to a semiconductor device and its manufacturing method, more specifically, to a semiconductor device comprising a nonvolatile memory using a high dielectric constant insulator as an interelectrode insulator, and its manufacturing method.

2. Description of the Related Art

In a semiconductor integrated circuit, miniaturization in feature size for realizing high integration and high performance has been accompanied by various problems.

For example, in a flash memory that is a nonvolatile memory, there is a problem concerning an interelectrode insulator between a floating gate (FG) and a control gate (CG) serving as a second gate of a memory cell transistor. As the interelectrode insulator, a silicon oxide (SiO₂) film, a silicon nitride (SiN) film, a silicon oxynitride (SION) film, or a laminated film thereof has widely been used. In a structure that uses such a film, since dielectric constant of a tunnel insulator and an interelectrode insulator are close each other, an area of the interelectrode insulator must be enlarged to increase a coupling ratio, consequently approaching a limit of the miniaturization based on current technology. To solve such a problem, studies have been conducted to use a high dielectric constant insulator, e.g., a tantalum oxide (Ta₂O₅) film used in a stacked dynamic-random access memory (stacked DRAM), as the interelectrode insulator.

It is because the high dielectric constant insulator has a greater dielectric constant compared with that of the SiO₂ film or the like, and thus a thickness of the insulator can be thickened when an interelectrode insulator providing the same capacitance is formed. Leakage characteristics of a capacitor are expected to improve by using thicker insulator. In reality, however, in the case of the high dielectric constant insulator, e.g., the Ta₂O₅ film, a leak current is greater while a film thickness is thicker than that of the SiO₂ film, and thus it is still not in use as an interelectrode insulator of the flash memory. One of possible causes of the greater leak current is that grain boundaries generated by crystallization of the Ta₂O₅ film work as leak paths.

A technology for reducing the leak current of the high dielectric constant insulator is disclosed in, e.g., Jpn. Pat. Appln. KOKAI Publication No. 2002-319583. According to this technology, a high dielectric constant insulator formed on a silicon substrate via a silicate interface film is used as a gate insulator. Since a crystallization temperature of the silicate interface film is high, a crystallization temperature of the high dielectric constant insulator is practically increased. Accordingly, the high dielectric constant insulator is not crystallized even through annealing at a high temperature. As a result, the leak current can be reduced.

Another possible cause to increase leak current is that there are many atoms having dangling (non-bonded) bonds in the high dielectric constant insulator film because of a deviation of the film composition from a stoichiometric composition. It is known that the dangling bonds in the insulator film form energy levels in an energy band gap, and the leak current flows via the levels. Thus, for example, studies have been conducted on a reduction in the leak current by executing separate post-oxidation after formation of the Ta₂O₅ film, and fixing the dangling bonds of the Ta atoms by oxygen. However, an additional post-oxidation step is required, thus the number of steps are increased.

Furthermore, in the stacked DRAM, to reduce the leak current of the interelectrode insulator, a technology that uses a laminated film of a hafnium oxide (HfO₂) film and an aluminum oxide (Al₂O₃) film as high dielectric constant insulators has been reported by, e.g., Jong-Ho Lee et. al., in 2002 Symposium On VLSI Technology Digest of Technical Paper (pp. 114-115, 2002). This technology presupposes use of an amorphous laminated film. On the other hand, in the case of the flash memory, it is unavoidable annealing for forming a metal oxide semiconductor (MOS) transistor after a high dielectric constant film formation. The annealing causes crystallization of the high dielectric constant film, which cannot be applied to the flash memory.

### BRIEF SUMMARY OF THE INVENTION

According to one aspect of the present invention, a semiconductor device comprises: a first insulator formed on a semiconductor substrate, a first gate electrode formed on the first insulator, a second gate electrode formed above the first gate electrode, and a second crystallized insulator formed between the first gate electrode and the second gate electrode.

According to another aspect of the present invention, a method for manufacturing a semiconductor device comprises: forming a first insulator on a semiconductor substrate, depositing a first conductive film on the first insulator, depositing a second amorphous insulator on the first conductive film, crystallizing the second insulator, and depositing a second conductive film on the second insulator.

### BRIEF DESCRIPTION OF THE SEVERAL VIEWS OF THE DRAWING

FIG. 1A is a sectional view showing an example of a semiconductor device according to a first embodiment;

FIG. 1B is an enlarged schematic view of a portion of an interelectrode insulator encircled with A in FIG. 1A, showing a state of grain boundaries in the interelectrode insulator;

FIGS. 2A to 2C are sectional views showing an example of a manufacturing process of the semiconductor device of the first embodiment;

FIG. 3 is a view illustrating leak current characteristics of the interelectrode insulator of the semiconductor device of the first embodiment;

FIG. 4 is a sectional view showing an example of a semiconductor device according to a second embodiment;

FIGS. 5A and 5B are sectional views showing an example of a manufacturing process of the semiconductor device of the second embodiment;

FIG. 6 is a view illustrating leak current characteristics of an interelectrode insulator of the semiconductor device of the second embodiment;

FIG. 7 is a sectional view showing an example of a semiconductor device according to a third embodiment;

FIGS. 8A and 8B are sectional views showing an example of a manufacturing process of the semiconductor device of the third embodiment; and

FIG. 9 is a view illustrating leak current characteristics of an interelectrode insulator of the semiconductor device of the third embodiment.

### DETAILED DESCRIPTION OF THE INVENTION

Examples of embodiment of the present invention will be described in detail with reference to the accompanying drawings. Throughout the drawings, corresponding portions are denoted by corresponding reference numerals.

The accompanying drawings, which are incorporated in and constitute a part of the specification, illustrate embodiments of the invention, and together with the general description given above and the detailed description of the embodiments given below, serve to explain the principles of the invention.

The use of a high dielectric constant insulator as an interelectrode insulator has been studied not only for a flash memory but also for a DRAM as described above. However, the high dielectric constant insulator for the flash memory is not handled similarly with that of the DRAM as annealing conditions after formation of interelectrode insulator are different between them. That is, in the case of the flash memory, annealing at a high temperature is necessary because a MOS transistor is formed after the interelectrode insulator is formed. On the other hand, in the case of the DRAM, such a high temperature annealing can be avoided because the interelectrode insulator is formed after a MOS transistor is formed. The high temperature annealing causes crystallization of the interelectrode insulator. The crystallized high dielectric constant insulator has a problem to increase leak current as described above. In a semiconductor device, leak current of a high dielectric constant insulator is suppressed by using a crystallized high dielectric constant insulator as an interelectrode insulator. A semiconductor device using the crystallized high dielectric constant insulator and its manufacturing method will be described by way of embodiments.

### First Embodiment

The first embodiment is designed to suppress leak current due to a grain boundary. The grain boundary in a high dielectric constant insulator is conceivably one of significant causes of an increase in the leak current when the high dielectric constant insulator is used as an interelectrode insulator.

Many crystal grains are formed in the high dielectric constant insulator when it is crystallized. Regarding such crystal grains, as crystal orientation is different between adjacent crystal grains, there are many atoms having unbonded bonds, i.e., dangling bonds, at the grain boundaries thereof. It is believed that if the grain boundary passes throughout the high dielectric constant insulator, leak current flows through the dangling bonds, and the grain boundary works as a leak current path as described above. Thus, according to the embodiment, the leak current is suppressed by preventing the grain boundary to propagate throughout the high dielectric constant insulator even if the insulator is crystallized.

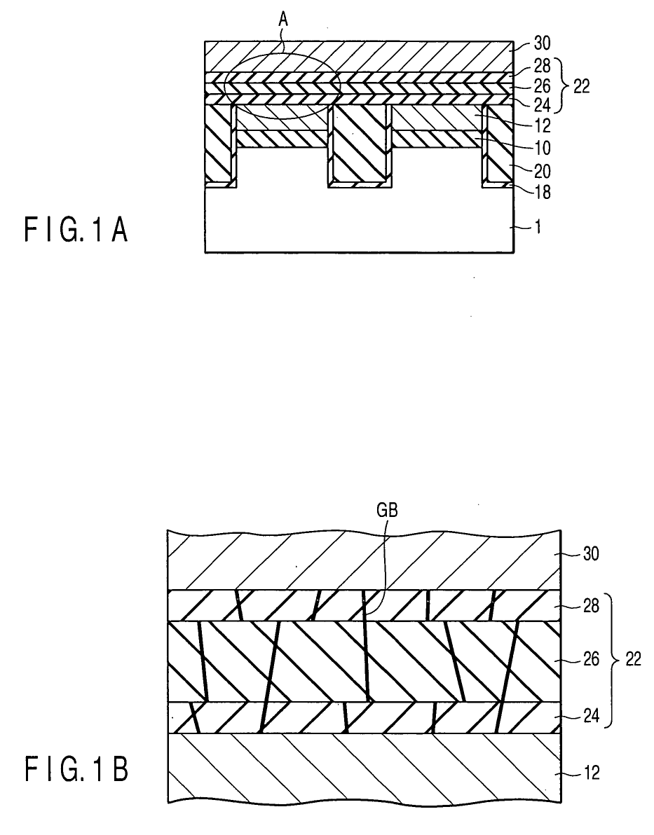

The first embodiment is shown in FIGS. 1A and 1B. FIG. 1A is a sectional view showing an example of a semiconductor device of the first embodiment. FIG. 1B is an enlarged view of a portion of an interelectrode insulator encircled with A in FIG. 1A. As shown in FIG. 1A, the embodiment is a nonvolatile memory with a so-called floating gate structure, e.g., a flash memory, which comprises a floating gate (FG) 12, a control gate (CG) 30, and an interelectrode insulator 22 disposed between these gate electrodes 12, 30. As shown in FIGS. 1A, 1B, the interelectrode insulator 22 is a laminated film 22 constituted of multiple layers, e.g., 3 crystallized insulator films (24, 26, and 28). Further, the interelectrode insulator 22 characteristically has a structure in which grain boundaries GB do not pass through the entire interelectrode insulator 22 as indicated by a thick line in FIG. 1B. This structure enables to segment the grain boundaries GB, which become leak paths of the leak current in the interelectrode insulator 22, and to reduce the leak current.

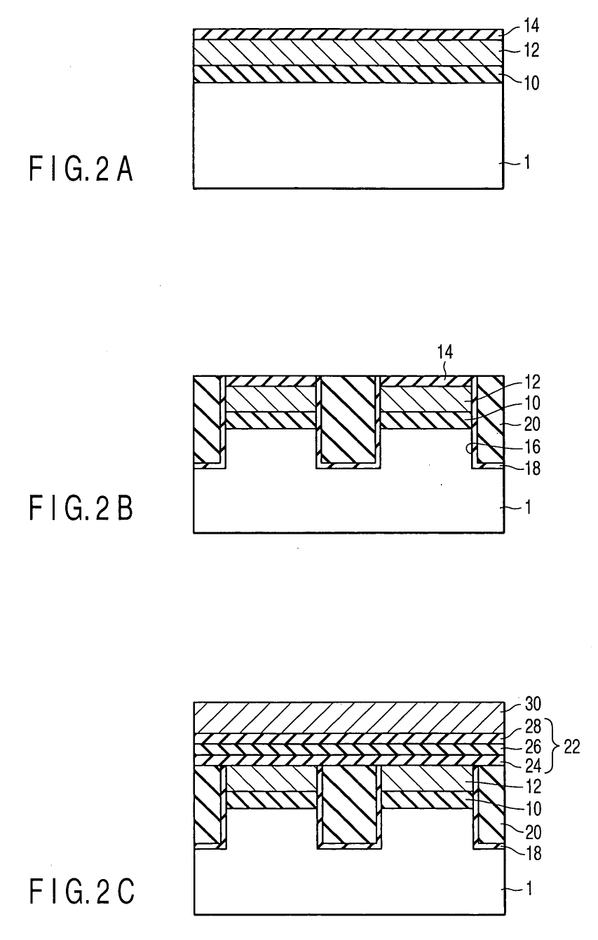

Hereinafter, a manufacturing process of the semiconductor device according to the embodiment will be described with reference to FIGS. 2A to 2C.

As shown in FIG. 2A, to begin with, a first insulator 10 is formed on an entire surface of a semiconductor substrate 1, e.g., a silicon (Si) substrate 1. The first insulator 10 is used as a tunnel insulator. For example, a silicon oxide (SiO₂) film formed by thermal oxidation, a silicon oxynitride (SiON) film formed by nitriding the SiO₂ film, or an SiNO film formed by oxidizing a silicon nitride (SiN) film can be used therefor. Then, a first polysilicon film 12 doped with impurities is deposited on an entire surface of the first insulator 10 by, e.g., low pressure chemical vapor deposition (LPCVD). The impurity to be doped can be phosphorus, for example. The first polysilicon film is subsequently patterned to form a floating gate. Further, an SiN film 14 is deposited on an entire surface of the first polysilicon film 12 by, e.g., plasma-assisted chemical Vapor deposition (PCVD).

Next, a pattern of an isolation is formed in the SiN film 14 by lithography. The first polysilicon film 12, and the first insulator 10 are sequentially removed by reactive ion etching (RIE) while the SiN film 14 is used as a mask, and a groove is further formed in the Si substrate 1 to form a trench 16 for isolation. After an inner wall of the trench 16 is thermally oxidized to form a second insulator (SiO₂ film) 18, a third insulator 20, e.g., an SiO₂ film, that becomes an isolation insulator is deposited on an entire surface of the second insulator 18 by CVD. Subsequently, chemical mechanical planarization (CMP) is executed by using the SiN film 14 as a stopper, so that the SiO₂ film 20 other than the isolation trench 16 is removed, whereby a structure shown in FIG. 2B is formed.

Further, a surface of the third insulator 20, that is an isolation SiO₂ film, is slightly removed, the SiN film 14 is removed to smooth the surface. Then an amorphous interelectrode insulator 22 is deposited on an entire surface. For the interelectrode insulator 22, high dielectric constant insulators of at least two kinds, which have different crystallization temperatures, may be used. For example, a 3-layered structure can be made in which a material with a higher crystallization temperature is interposed between materials with lower crystallization temperatures. In this embodiment, a transition metal oxide in the group 4A of a periodic table, e.g., a hafnium oxide (HfO₂) film, is used as a material with a lower crystallization temperature, and an aluminum oxide (Al₂O₃) film is used as a material with a higher crystallization temperature. As the transition metal oxide in the group 4A of the periodic table, in addition to the HfO₂, e.g., a zirconium oxide (ZrO₂) or a titanium oxide (TiO₂) may be used. The amorphous interelectrode insulator 22 is deposited by atomic layer deposition (ALD). A three layered laminate film 22 of HfO₂ film 28/Al₂O₃ film 26/HfO₂ film 24 is formed with, e.g., 4 nm, 10 nm, and 4 nm in thickness, respectively. Then, after crystallization of the interelectrode insulator 22 (detailed later), a second polysilicon film 30 doped with, e.g., phosphorus is deposited to constitute a control gate (CG), whereby a structure shown in FIG. 2C can be formed.

Subsequently, through a manufacturing process of a MOS transistor such as formation of a gate and a source/drain, and a multilevel wiring or the like, a semiconductor device that has a floating gate structure, for example, flash memory is formed.

Next, the crystallization of the interelectrode insulator 22 will be described. All of the HfO₂ films 24, 28 and the Al₂O₃ film 26 are not crystallized, i.e., amorphous, just after the deposition by ALD. Crystallization temperatures of the amorphous HfO₂ film and Al₂O₃ film are experimentally known about 500° C. or higher and about 800° C. or higher, respectively. Accordingly, annealing for the crystallization of the interelectrode insulator 22 is carried out in two stages. That is, a first annealing is executed at a temperature higher than a crystallization temperature of the HfO₂ film and lower than that of the Al₂O₃ film, i.e., a temperature between 500° C. and 800° C., e.g., 750° C., to crystallize only the HfO₂ films 24, 28 first. Then, a second annealing is executed at a temperature higher than a crystallization temperature of the Al₂O₃ film 26, i.e., 800° C., e.g., 900° C., to crystallize the Al₂O₃ film 26. Lattice structures of the crystallized HfO₂ and Al₂O₃ films are different from each other. Thus, even if one amorphous film (Al₂O₃ film 26 in this case) is crystallized while contacting with other crystallized films (HfO₂ films 24, 28 in this case), the film (Al₂O₃ film 26) crystallized later may be crystallized without suffering from the lattice structures of the previously crystallized films. That is, the lately crystallized Al₂O₃ film 26 can be crystallized independently of the previously crystallized HfO₂ films 24, 28. Thus, grain boundaries of the HfO₂ films 24, 28 are not propagated in the Al₂O₃ film 26, generally. As a result, the grain boundaries GB become discontinuous at interfaces of the HfO₂ films 24, 28 and the Al₂O₃ film 26, and never pass through the entire laminated insulator 22.

To verify the aforementioned model, cross-sectional observation by a transmission electron microscope (TEM) has been conducted (referred to as cross-sectional TEM observation, hereinafter). A result confirms that in the laminated film 22 of HfO₂ film 28/Al₂O₃ film 26/HfO₂ film 24, as schematically shown in FIG. 1B, the grain boundaries GB in the HfO₂ films 24, 28 of the lower and upper layers are hardly propagated into the Al₂O₃ film 26 interposed therebetween. Even if a grain boundary in an HfO₂ film is propagated into the Al₂O₃ film 26, the grain boundary is never propagated into another HfO₂ film on the opposite side as it has been already crystallized. Therefore, it has been verified that the grain boundaries do not pass through the entire laminated interelectrode insulator 22. On the other hand, a result of cross-sectional TEM observation of single Al₂O₃ film crystallized at the same temperature shows that grain boundaries pass throughout the Al₂O₃ film from the front surface to the backside.

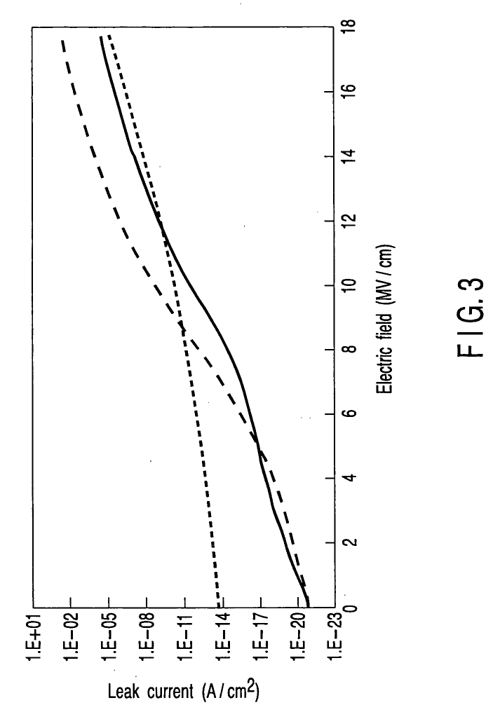

Leak current of the interelectrode insulator 22 has measured on the semiconductor device having the 3-layered interelectrode insulator 22 formed in the aforementioned manner. As a reference, leak current of interelectrode insulator 22 with single HfO₂ film or single Al₂O₃ film has been measured. FIG. 3 shows results of the leak current measurement, wherein a horizontal axis indicates electric field of the interelectrode insulator, and a vertical axis indicates leak current thereof. In FIG. 3, a solid line represents leakage characteristics of the 3-layered laminated film according to the embodiment, a dotted line represents leakage characteristics of the single HfO₂ film, and a broken line represents leakage characteristics of the single Al₂O₃ film. Compared with the single HfO₂ film, leak current of the 3-layered laminated film of the embodiment is much less in an electric field of 12 MV/cm and less. Compared with the single Al₂O₃ film, the leak current of the 3-layered laminated film is less in an electric field of 5 MV/cm and higher. An electric field applied to the interelectrode insulator 22 in a flash memory is, for example, about 4 MV/cm for data retention, about 9 MV/cm for data readout, and about 18 MV/cm for data writing. It has been verified that the leak current of the laminated interelectrode insulator 22 of the embodiment is less in all the electric fields for such device operations, which is favorable for the interelectrode insulator of the flash memory.

Thus, it is possible to reduce leak current between the FG and the CG by crystallizing the interelectrode insulator 22 not to pass the grain boundaries GB thereof throughout the interelectrode insulator 22.

The embodiment has been described by way of the structure in which the Al₂O₃ film with the higher crystallization temperature is held between the HfO₂ films with the lower crystallization temperatures. However, the invention is not limited to this structure and the materials, and various modifications may be made. For example, a structure may be made in which a high dielectric constant insulator with a lower crystallization temperature may be interposed between high dielectric constant insulators with higher crystallization temperatures. Any laminated film structure may be acceptable if a grain boundary does not pass throughout the laminated film, that is a multilayered laminated structure of not 3-layered but 4 or more layered may be available in which, for example, an Al₂O₃ film is further disposed on HfO₂ film/Al₂O₃ film/HfO₂ film. The material of the high dielectric constant film has been described by way of the combination of similar materials. However, different materials may be combined. For example, HfO₂, ZrO₂, TiO₂, a tantalum oxide (Ta₂O₅), Al₂O₃, and a mixture thereof may be used. Additionally, it may be disposed a film of a material, which is not generally called a high dielectric constant insulator, such as a silicon oxide, a silicon nitride, or a silicon oxynitride, at an interface between the interelectrode insulator and the FG and/or the CG.

As described above, according to the embodiment, it is provided a semiconductor device using a high dielectric constant insulator having reduced leak current as an interelectrode insulator, and its manufacturing method.

### Second Embodiment

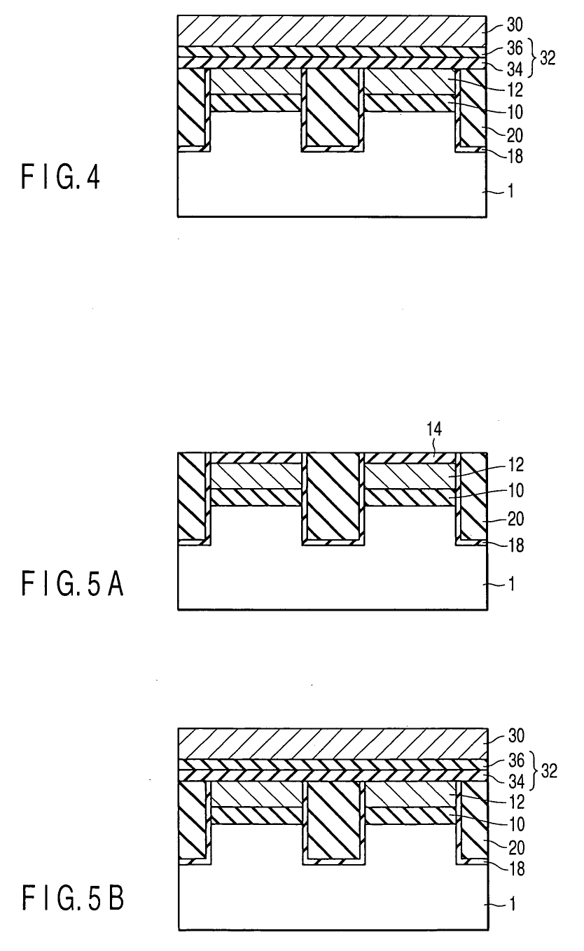

The second embodiment is designed to reduce leak current caused by an oxygen defect in an interelectrode insulator. FIG. 4 is a sectional view showing an example of a semiconductor device according to the second embodiment. As shown in FIG. 4, the embodiment is a nonvolatile memory of a so-called floating gate structure, which comprises a floating gate (FG) 12, a control gate (CG) 30, and an interelectrode insulator 32 interposed between these gate electrodes. The interelectrode insulator 32 is a 2-layered laminated film constituted of crystallized insulators 34, 36. The interelectrode insulator 32 is characterized by a structure in which an oxygen defect in the lower insulator 34 is recovered by oxygen supplied through the upper insulator 36. This structure enables a reduction in leak current of the interelectrode insulator 32 by reducing a density of oxygen defects, which act as a leak path of the leak current.

A manufacturing process according to the second embodiment is generally similar to that of the first embodiment, but a forming process of the interelectrode insulting film 32 is different. Hereinafter, the manufacturing process of the embodiment will be described with reference to FIGS. 5A and 5B.

FIG. 5A is a view of a sectional structure similar to that in FIG. 2B, wherein a first insulator (tunnel insulator) 10 is formed on an Si substrate 1, a first polysilicon film 12 and an SiN film 14 are sequentially deposited, and then patterned to form an isolation using a third insulator (isolation SiO₂ film) 20, and the surface is planarized.

Further, surface of the isolation SiO₂ film 20 is slightly removed, and the SiN film 14 is removed to smooth the surface. Next, a 2-layered amorphous interelectrode insulator 32 is formed by ALD. An Al₂O₃ film 34 having relatively good in leakage characteristics is formed as a lower high dielectric constant insulator, and a transition metal oxide in the group 4A of a periodic table, e.g., an HfO₂ film 36, is formed as an upper layer. These films are set to, e.g., 10 nm and 4 nm in thickness, respectively. Then, crystallization annealing is carried out in an oxygen containing atmosphere, for example, of an oxygen concentration of 1% and at a temperature of 900° C. In this annealing, the Al₂O₃ film 34 and the HfO₂ film 36 are simultaneously crystallized. In this case, as detailed later, the HfO₂ film works as a source of an active oxygen supply to the Al₂O₃ film, and an oxygen defect in the Al₂O₃ film is recovered by the active oxygen. Subsequently, for example, a polysilicon film 30 doped with phosphorus is deposited to be constituted a control gate (CG), whereby a structure shown in FIG. 5B can be formed.

Subsequently, through a manufacturing process of a MOS transistor such as formation of a gate and a source/drain, and a multilevel wiring or the like, a flash memory semiconductor device that has a floating gate structure, for example, is formed.

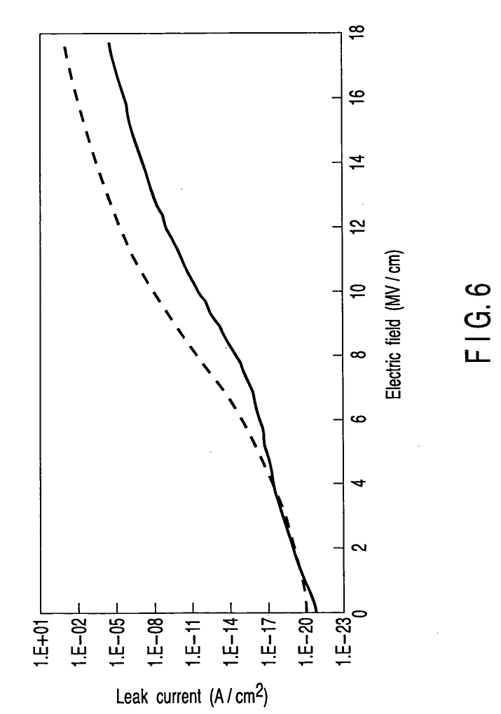

Leak current of the interelectrode insulator 32 has measured on the semiconductor device having the 2-layered interelectrode insulator 32 formed in the aforementioned manner. As a reference, leak current of the interelectrode insulator 32 with the same structure crystallized in an atmosphere without oxygen has been measured. FIG. 6 shows results of the leak current measurement, wherein a horizontal axis indicates electric field of the interelectrode insulator, and a vertical axis indicates leak current thereof. In FIG. 6, a solid line represents leakage characteristics of the 2-layered interelectrode insulator 32 according to the embodiment crystallized in an atmosphere containing oxygen, and a broken line represents leakage characteristics of the 2-layered interelectrode insulator crystallized in an atmosphere without oxygen. It has been verified that the leak current of the 2-layered interelectrode insulator 32 of the embodiment crystallized in the atmosphere containing oxygen is less especially on a high electric field side of 4 MV/cm and higher compared with that of the interelectrode insulator crystallized in the atmosphere without oxygen. The leak current characteristics are improved within an electric field range of about 4 MV/cm to 19 MV/cm used in the aforementioned flash memory operation. That is, it is verified to reduce the leak current of the laminated interelectrode insulator 32 by crystallizing it in the atmosphere containing oxygen.

A reason for reducing the leak current of the interelectrode insulator 32 according to the embodiment may be considered as follows. Leak current in the single Al₂O₃ film 34 is favorably low in a lower electric field of 4 MV/cm and less. Beyond this electric field, however, the leak current is suddenly increased. This may be attributed to the fact that dangling bonds caused by an oxygen defect in the Al₂O₃ film form levels in a band gap, and the leak current flows through the levels when a high electric field is applied to the Al₂O₃ film. Thus, it is possible to reduce the leak current of the high dielectric constant insulator by recovering the oxygen defect in the Al₂O₃ film to reduce a dangling bond density.

However, since diffusion of oxygen is slow in the Al₂O₃ film, it is difficult to sufficiently recover the oxygen defect by an annealing in an atmosphere containing oxygen in a standard manner. By the way, diffusion of oxygen is not only fast in the HfO₂ film, but also molecular oxygen diffused in the HfO₂ film is decomposed into active atomic oxygen therein. This atomic oxygen diffuses and reacts more easily than the molecular oxygen. Accordingly, the atomic oxygen may be quickly diffused into the Al₂O₃ film to recover the oxygen defect.

Under excessive annealing condition, e.g., a high-temperature annealing, a long-time annealing, or a high oxygen concentration, there might occur that oxygen diffuses to pass through the Al₂O₃ film to form an oxide film at an interface with an underlying polysilicon film (FG). To prevent such a problem, proper annealing conditions may be selected: for example, an annealing temperature is set to 800° C. to 950° C., an annealing time is set to 5 to 60 seconds, and an oxygen concentration is set in a range of 0.1% to 90%. Alternatively, an SiN film may be inserted between the Al₂O₃ film and the FG to prevent oxidation of the FG.

The embodiment has been described by way of the case in which the HfO₂ film is formed on the Al₂O₃ film. However, a film formed on the Al₂O₃ film is not limited to the HfO₂ film. Other high dielectric constant films such as a ZrO₂ film can be used as long as it is a film in which active oxygen can be supplied to the Al₂O₃ film by decomposing oxygen or the like.

The embodiment has been described by way of the example of the 2-layered laminated film. However, as in the case of the first embodiment, a 3-layered structure of HfO₂ film/Al₂O₃ film/HfO₂ film or the like, or a multilayered laminated structure of more layers may be formed.

As described above, according to the second embodiment, it is provided a semiconductor device using a high dielectric constant insulator having reduced leak current as an interelectrode insulator, and its manufacturing method.

### Third Embodiment

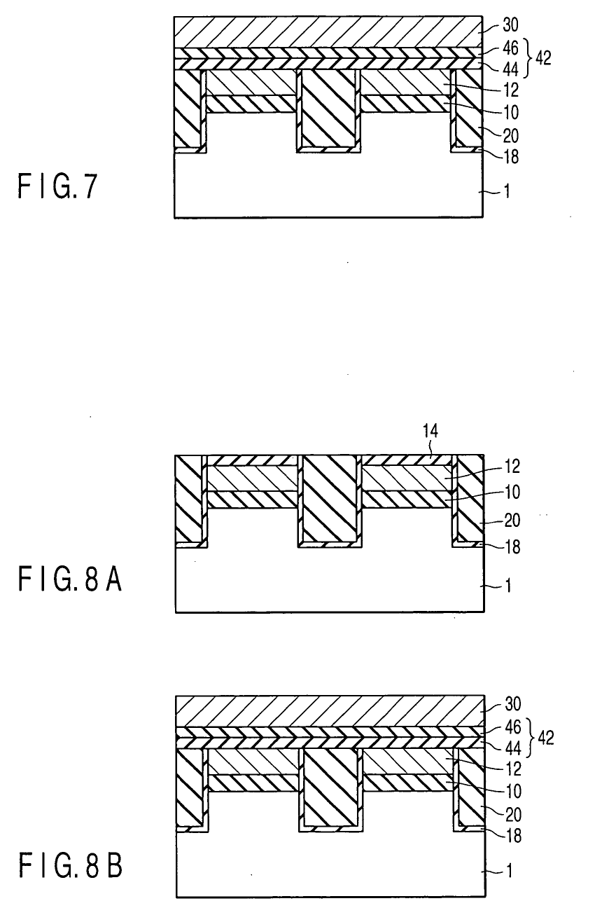

The third embodiment is designed to suppress a leak current caused by strain in an interelectrode insulator. As shown in FIG. 7, the embodiment is a nonvolatile memory of a so-called floating gate structure, which comprises a floating gate (FG) 12, a control gate (CG) 30, and an interelectrode insulator 42 interposed between these gate electrodes. The interelectrode insulator 42 is a 2-layered laminated film 42 constituted of crystallized insulators 44, 46. The interelectrode insulator 42 is characterized by a structure in which the lower insulator 44 has Young's modulus less than that of the upper insulator 46, and contraction strain in the upper insulator 46 caused by shrinkage of the insulators 44, 46 in a crystallization of amorphous film is relaxed by the lower insulator 44. This structure enables to reduce leak current of the interelectrode insulator 42 by relaxing overall strain in the entire insulator 42, which causes the leak current.

A manufacturing process of the embodiment is generally similar to those of the first and second embodiments, but a forming process of the interelectrode insulting film 42 is different. Hereinafter, the manufacturing process of the third embodiment will be described with reference to FIGS. 8A and 8B.

FIG. 8A is a view of a sectional structure similar to that in FIG. 2B, wherein a tunnel insulator 10, a first polysilicon film 12 and an SiN film 14 are sequentially deposited on an Si substrate 1, and then patterned to form an isolation using an isolation SiO₂ film 20, and the surface is planarized.

Further, surface of the isolation SiO₂ film 20 is slightly removed, and the SiN film 14 is removed to smooth the surface. Next, a 2-layered amorphous interelectrode insulator 42 is formed by ALD. A lower high dielectric constant insulator is made of a transition metal oxide in the group 4A of a periodic table, e.g., an HfO₂ film 44 having Young's modulus less than that of an upper Al₂O₃ film 46. The HfO₂ film 44 and the Al₂O₃ film 46 are set to, e.g., 4 nm and 10 nm in thickness, respectively. Then, crystallization annealing is carried out at, e.g., 900° C. In this annealing, the HfO₂ film 44 and the Al₂O₃ film 46 are almost simultaneously crystallized. Subsequently, for example, a polysilicon film 30 doped with phosphorus is deposited to constitute a control gate (CG), whereby a structure shown in FIG. 8B can be formed.

Subsequently, through a manufacturing process of a MOS transistor such as formation of a gate and a source/drain, and a multilevel wiring or the like, a flash memory semiconductor device that has a floating gate structure, for example, is formed.

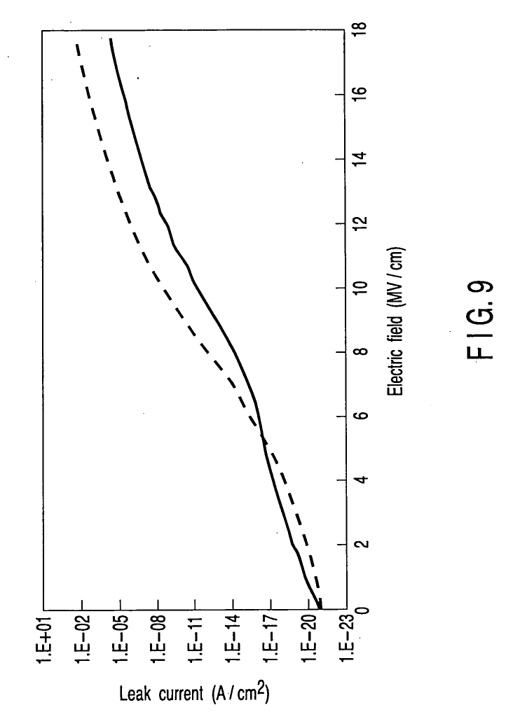

Leak current of the interelectrode insulator 42 has measured on the semiconductor device having the 2-layered interelectrode insulator 32 formed in the aforementioned manner. As a reference, leak current of the interelectrode insulator with single Al₂O₃ film has been measured. FIG. 9 shows results of the leak current measurement, wherein a horizontal axis indicates electric field of the interelectrode insulator, and a vertical axis indicates leak current thereof. In FIG. 9, a solid line represents leakage characteristics of the 2-layered interelectrode insulator 42 of the embodiment, and a broken line represents leakage characteristics of the single Al₂O₃ film. It has been verified that a leak current of the 2-layered interelectrode insulator 42 of the embodiment is less in an electric field of 5 MV/cm and higher compared with that of the single Al₂O₃ film, and both are almost equivalent in an electric field of 5 MV/cm or less. The leak current characteristics are improved within an electric field range of about 4 MV/cm to 19 MV/cm used in the aforementioned flash memory operation.

A reason for the reduction in the leak current of the 2-layered interelectrode insulator 42 of the Al₂O₃ film 46 and the HfO₂ film 44 of the embodiment is considered as follows. When an amorphous insulator film deposited by ALD is crystallized, volume contraction of about 10% occurs, generally. That is, the HfO₂ film 44 and the Al₂O₃ film 46 are both contracted to generate strain against an underlying polysilicon film 12. Young's moduli of the HfO₂ film 44 and Al₂O₃ film 46 are 240 GPa and 400 GPa, respectively. The lower HfO₂ film 44 contacting with the polysilicon film 12 has less Young's modulus than the upper Al₂O₃ film 46. A film with less Young's modulus is softer, and less strain generated against the underlying film contacting thereto. Accordingly, when the Al₂O₃ film 46 with greater Young's modulus is formed on the polysilicon film 12 by sandwiching a film with less Young's modulus, e.g., the HfO₂ film 44, contraction strain due to crystallization can be reduced to a lower value than when the Al₂O₃ film 46 is formed directly on the polysilicon film 12. As a result, the leak current of the interelectrode insulator 42 may be reduced.

In the embodiment, the polysilicon film 30 constituting the CG is formed after the crystallization of the interelectrode insulator 42. However, the interelectrode insulator 42 can be crystallized after the polysilicon film 30 is formed. In this case, a material with less Young's modulus is further used in a portion of the interelectrode insulator 42 contacting with the upper polysilicon film 30 (CG) to reduce strain caused by crystallization of the interelectrode insulator 42, that is a 3-layered structure of, e.g., HfO₂ film/Al₂O₃ film/HfO₂ film may be effective.

As described above, according to the embodiments, it is provided a semiconductor device using a high dielectric constant insulator having reduced leak current as an interelectrode insulator, and its manufacturing method.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

1. A semiconductor device comprising:
a first insulator formed on a semiconductor substrate;
a first gate electrode formed on the first insulator;
a second gate electrode formed above the first gate electrode; and
a second crystallized insulator formed between the first gate electrode and the second gate electrode.

2. The semiconductor device according to claim 1, wherein the second insulator is a crystallized laminated layer comprised of a plurality of high dielectric constant insulating materials.

3. The semiconductor device according to claim 1, wherein the second insulator is formed in amorphous and then crystallized.

4. The semiconductor device according to claim 1, wherein a grain boundary of the second insulator does not pass through the second insulator.

5. The semiconductor device according to claim 2, wherein a grain boundary of the second insulator does not pass through the second insulator.

6. The semiconductor device according to claim 2, wherein the second insulator is a laminated film of at least three layered, and a crystallization temperature of an upper layer and a lower layer of the second insulator is different from that of a middle layer thereof.

7. The semiconductor device according to claim 2, wherein the second insulator comprises an oxide film of a transition metal in the group 4A of the periodic table and an aluminum oxide film.

8. The semiconductor device according to claim 1, wherein the second insulator is a laminated film of at least two layered, and an oxygen diffusion coefficient in a lower layer of the second insulator is less than that in an upper layer thereof.

9. The semiconductor device according to claim 2, wherein the second insulator is a laminated film of at least two layered, and an oxygen diffusion coefficient in a lower layer of the second insulator is less than that in an upper layer thereof.

10. The semiconductor device according to claim 9, wherein the lower layer of the second insulator is an aluminum oxide film, and the upper layer thereof is an oxide film of a transition metal in the group 4A of the periodic table.

11. The semiconductor device according to claim 2, wherein the second insulator is a laminated film comprised of a plurality of high dielectric constant insulating materials having different elastic constants.

12. The semiconductor device according to claim 11, wherein the elastic constant of the lower layer of the second insulator is less than that of the upper layer thereof.

13. The semiconductor device according to claim 11, wherein the lower layer of the second insulator is an oxide film of a transition metal in the group 4A of the periodic table, and the upper layer thereof is an aluminum oxide film.

14. A method for manufacturing a semiconductor device comprising:
forming a first insulator on a semiconductor substrate;
depositing a first conductive film on the first insulator;
depositing a second amorphous insulator on the first conductive film;
crystallizing the second insulator; and
depositing a second conductive film on the second insulator.

15. The method according to claim 14, wherein the second insulator is a laminated film comprised of a plurality of high dielectric constant insulating materials.

16. The method according to claim 14, wherein the second insulator is a laminated film of at least three layered; and the crystallizing step comprises crystallizing an upper layer and a lower layer of the second insulator at a first crystallization temperature, and crystallizing a middle layer of the second insulator at a second crystallization temperature.

17. The method according to claim 16, wherein the crystallizing step is accomplished by first carrying out at lower one of the first crystallization temperature or second crystallization temperatures, and then carrying out at the other crystallization temperature after heating up.

18. The method according to claim 15, wherein the second insulator comprises an oxide film of a transition metal in the group 4A of the periodic table and an aluminum oxide film.

19. The method according to claim 15, wherein the crystallizing step of the second insulator is carried out in an atmosphere containing oxygen.

20. The method of according to claim 19, wherein a step of depositing the second insulator comprises depositing an aluminum oxide film, and depositing an oxide film of a transition metal in the group 4A of the periodic table.
